(19) United States
(12) Patent Application Publication
(10) Pub. No.: US 2008/0164564 A1
(43) Pub. Date: Jul. 10, 2008

(54) Micromechanical component having integrated passive electronic components and method for its production

(76) Inventors: Heiko Stahl, Reutlingen (DE); Christian Ohl, Pfullingen (DE); Frank Fischer, Gomaringen (DE)

Correspondence Address: KENYON & KENYON LLP, ONE BROADWAY, NEW YORK, NY, 10004, US

(21) Appl. No.: 12/001,531

(22) Filed: Dec. 11, 2007

(30) Foreign Application Priority Data
Dec. 14, 2006 (DE) 102006059084.8

(51) Int. Cl. H01L 29/92; H01L 21/02

(52) U.S. Cl. 257/532; 438/393; 257/E29.342; 257/E21.008

(57) ABSTRACT

A micromechanical component includes a substrate, on which at least one layer sequence is situated, which includes at least one micromechanical functional element, and on which at least one layer sequence is situated that is able to act as at least one macroelectronic, passive component.

### FIELD OF THE INVENTION

The present invention relates to a micromechanical component having integrated passive electronic components and a method for producing it. Micromechanical components are often used in miniaturized sensors, in security systems of motor vehicles, for example.

### BACKGROUND INFORMATION

It is known that one may manufacture monolithically integrated sensors. In this context, using various processing steps of microprocess technology as successions of depositing steps and patterning steps, self-supporting mechanical structures are generated having specifically deflectable functional layers, which are mostly incorporated in the form of chips as sensitive components into more complex devices. Although the preparation of the micromechanical component as an integrated component in the form of so-called MEMS stacks (microelectromechanical systems) has in connection with it, in part, a considerable reduction in application expenditure when compared to discrete construction, but when it comes to assembly to a functionally complete unit, as a rule, there remains the need for a costly circuit engineering embedding of the micromechanical component.

In order to reduce costs for the circuit engineering embedding of micromechanical components in an overall system having corresponding evaluation functions and control functions, highly integrated electronic components, preferably so-called ASIC's, are used also for the necessary evaluation and control circuits.

It is known that one may combine on one chip an evaluation circuit based on CMOS or mixed processes with MEMS components. Sensors designed in that way already have a complete functionality, protective encapsulation, such as packaging in a mold housing, being undertaken in addition.

It is further known that one may increase the effective degree of integration by the so-called “system-in-package”. In this context, individual components, for instance, a micromechanical chip module and an ASIC having the associated evaluation circuit are accommodated in a common housing and are interconnected. Sensors developed this way also have complete functionality.

For many automotive applications, sensors packaged in housings are combined on a printed-circuit board together with additional components external to the package, or are incorporated in hybrid circuits. What occurs particularly frequently is a combination of sensors packaged in housings and external back-up capacitors that are required for buffering ESD-conditioned (electrostatic discharge) voltage peaks. In the automotive field, these have to be buffered particularly if the sensor module is not integrated into an overall protected control unit, but is connected directly to the voltage supply of the vehicle electrical system. A direct integration of buffer capacitors into the ASIC's used is connected with considerable technical difficulties, based on extremely different dimensions and interactions that are to be expected of large charge transfers during reloading of the capacitors in the immediate vicinity of microelectronic structures

### SUMMARY OF THE INVENTION

An object of the present invention is to provide a possibility of further lowering the expenditure in the application of micromechanical sensors compared to the related art, and to reduce the installation space required, so as to develop new installation locations, if necessary.

The present invention starts from the idea that surface areas and volume regions exist in MEMS structures which, in contrast to regions of high integration density and sensitivity to interference, that are present in ASIC's and other micromechanical circuits, experience no impairment of their functionality by an integration of passive, macroelectronic components. It has turned out that in these regions, according to the present invention, for instance, a direct integration of buffer capacitors is possible, without one's having to accept mechanical or electrical impairment of systems made up of micromechanical components and integrated evaluation circuits because of the action of even relatively large charge transfers, during reloading of the capacitors, for instance, during the occurrence of voltage peaks that are to be buffered. The present invention is embodied by a micromechanical component, including a substrate on which there is situated at least one layer sequence that includes at least one micromechanical functional element and forms a first functional region, and on which there is situated at least one layer sequence which acts, or is able to act as at least one macroelectronic, passive component and forms a second functional region. By macroelectronic components, within the meaning of the present invention, one should understand passive components that, by their dimensioning, are able to replace individual, normally discretely available and interconnected components.

The present invention may be implemented by methods for producing a micromechanical component in which at least one micromechanical functional layer is produced by successive depositing steps and patterning steps, depositing steps and/or patterning steps being undertaken which generate at least one layer sequence on the same substrate, which is able to act as at least one macroelectronic, passive component.

Relatively large capacitors, whose dimensioning permits their use as buffer capacitors for the protection of micromechanical circuits, are particularly advantageously integrated into micromechanical components.

Particularly, space-saving components according to the present invention may be built if at least one layer sequence, which acts as a macroelectronic, passive component, is located between the layer sequence, that includes at least one micromechanical functional element, and the substrate. Besides, in this case, serial processing is made possible, that permits an independent adjustment and optimization of the individual process steps.

However, one should advantageously take care, in this context, that surface areas of the substrate, over which layer stacks are located, which are used as passive electronic components, and surface areas over which printed-circuit traces run for contacting micromechanically effective patternings, lie next to one another in the wafer plane, since, in that way, interfering interactions may be avoided in a simple manner by keeping appropriate minimum separation distances.

### BRIEF DESCRIPTION OF THE DRAWINGS

FIG. 1 shows the construction in principle of a micromechanical component according to the present invention.

FIG. 2 shows the construction in principle of a micromechanical component according to the present invention, having an underlayed passive component.

FIG. 3 shows a detailed sectional representation of a micromechanical component according to the present invention.

FIG. 4 shows a schematic representation of a functional unit having a micromechanical component according to the present invention.

### DETAILED DESCRIPTION

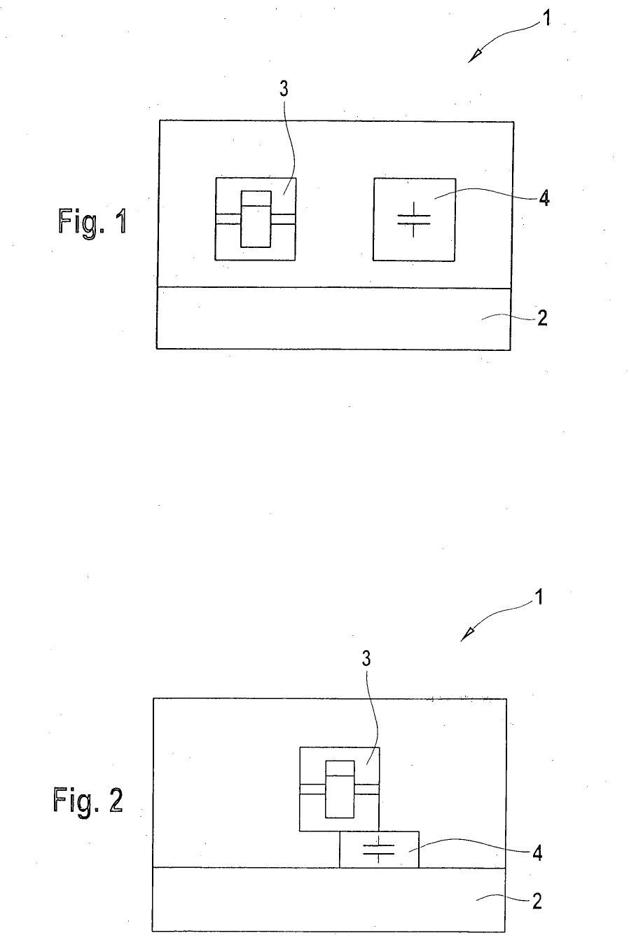

FIG. 1 shows the construction in principle of a micromechanical component 1 according to the present invention. On a common substrate 2 made of monocrystalline silicon, it has at least one functional area 3 which includes at least one micromechanical functional element. On the same substrate 2, according to the present invention, there is an additional functional area 4, which includes a structure, applied by microprocessing technology, that is able to act as at least one macroelectronic, passive component. Functional areas 3, 4, within the meaning of the present invention, are processed layer sequences, in this context, having definable functionality, if necessary, while assigning individual layers to several functional regions.

FIG. 2 shows the construction in principle of a micromechanical component 1 according to the present invention, having an underlayed passive component. Functional regions 3, 4, introduced in FIG. 1, in this case lie at least partially in different planes of micromechanical component 1, which develops the advantages of serial processing and makes possible space-saving designs.

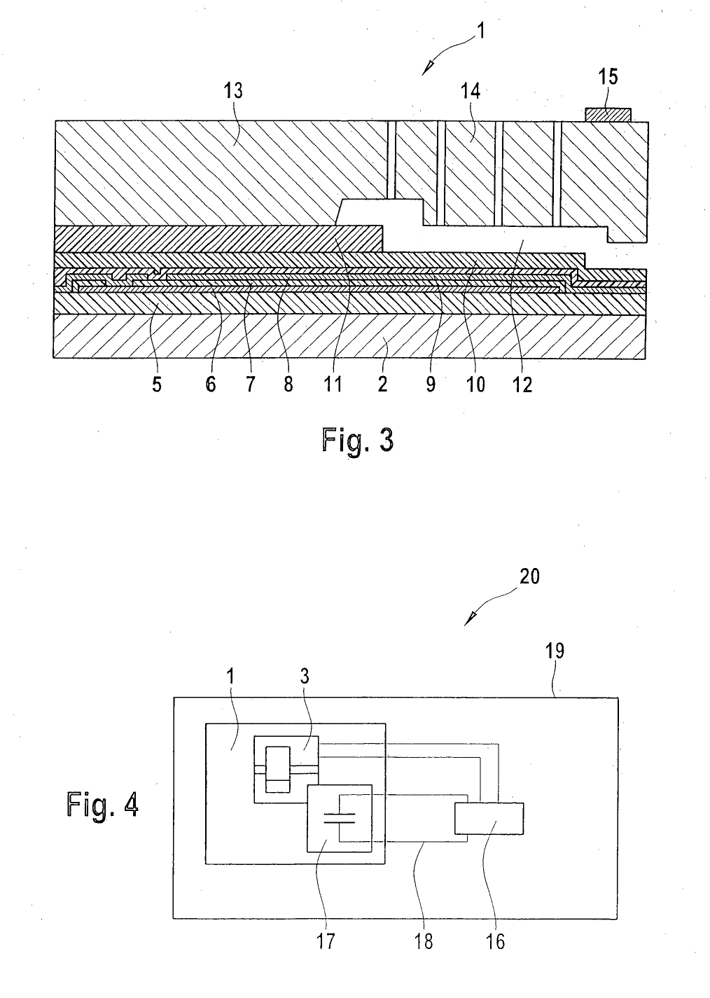

FIG. 3 shows a detailed sectional representation of a micromechanical component 1 according to the present invention, in which there is a layer stack, underneath a region having micromechanical functional elements, which is able to act as a capacitor. The system is located on a Si substrate 2, which is covered by an insulating layer 5. Insulating layer 5 is made up of a thermal oxide that is produced in a known manner (e.g. including 2.5 μm field oxide). On top of it there is a lower junction electrode 6, in the present diagram in the form of a layer of doped polycrystalline silicon 275 nm in thickness, three-valent or five-valent elements (e.g. P, As, B) being used as doping agents, since both conductivity types are suitable for the development of the electrode. On lower junction electrode 6 there is a layer 7 that acts as a dielectric, which is developed as a so-called ONO stack (oxide-nitride-oxide). In the present example, the stack begins with a layer of thermal oxide 27 nm in thickness. On top of that there is a reactively deposited nitride layer 15 nm in thickness (depositing by LPCVD). This is followed by an oxide layer of 5 nm thickness made of reoxidized nitride. Directly over the dielectric, there is an upper junction electrode 8 made of polycrystalline silicon 450 nm in thickness. This device may be used as a surface capacitor. In response to appropriate patterning of electrodes 6, 8, several independent capacitors may also be produced in one plane.

On the layer stack described, which is able to act as a capacitor, there is an additional layer stack which has at least one micromechanical functional layer in the usual way, which in the present case includes specifically deflectable seismic masses for measuring accelerations. This upper stack includes, in detail, a plurality of insulating layers 9, 10, 11, which are used simultaneously for mechanical profiling of the further construction, volumes 12 that are intermittently filled with the material of a sacrificial layer, as well as the actual mechanical functional layer 13 which, after the dissolving out of the sacrificial layer in an appropriate etching step, includes movable functional elements in the form of seismic masses 14. Regions to be contacted have a metallization layer 15, in addition.

The two layer stacks shown do not have to overlap over their whole surface. The exemplary layer construction has a capacity of approximately 1.1 nF/mm². Especially when using the capacitors, integrated in the manner according to the present invention, as buffer capacitors for microelectronic circuits, it is, however, expedient if at least parts of substrate 2 are covered by at least one insulating layer 5, on which there is located at least one lower plate electrode 6, on which there is located at least one upper plate electrode 8, on which there is located at least one insulating layer 9, as component of a layer sequence that includes at least one micromechanical functional element, that is, there is present at least one partial overlapping of the two layer stacks and functional regions 3, 4 of micromechanical component 1, according to the present invention.

In addition, for reasons of a minimized interaction between the individual functional regions 3, 4, it is advantageous if surface areas of the substrate, over which layer stacks are located that are utilized as passive electronic components, lie within the range of the bonding frame. In this case, the chip size of a micromechanical component, such as in an acceleration or yaw rate sensor, is not increased, unless the area of the bonding frame has to be increased, because of the increased number of contact pads that are now also required for contacting the passive components. One should understand bonding frame to mean the area used by a micromechanical component for the encapsulation of the sensor structure using an encapsulation structure as connecting surface.

One advantageous specialty of this exemplary embodiment is that a conductive layer is used in the process plane as upper junction electrode 8, in which layer are also located the lower contacting traces of the micromechanical layer stack that is located above the capacitor structure, the contacting traces being developed in the form of buried printed-circuit traces. This makes no basic requirement on systems according to the present invention. However, it is at least advantageous if the upper junction electrode lies at least partially in a plane with printed-circuit traces developed as buried printed-circuit traces for contacting areas to be contacted of the layer sequence lying above them, since in this case a common processing is able to take place of the printed-circuit traces and electrode surfaces required for both functional areas.

Corresponding to the present exemplary embodiment, individual details may be supplemented or replaced by modifications functioning in the same way, particularly of the materials used and the dimensions selected. For example, against the background of microprocess technology, other dielectric layers, especially IC-compatible dielectrics having a particularly high relative permittivity and a good temperature stability may be used and preferred, since the dielectrics have to withstand doping processes and epitaxy processes.

FIG. 4 shows a schematic representation of a functional unit 20 having a micromechanical component 1 according to the present invention. In it, a micromechanical component 1 is combined with at least one microelectronic component 16, to form a functional unit 20, there being an interconnection inside functional unit 20 which incorporates capacitors 17, integrated into the micromechanical component, as buffer capacitors for microelectronic component 16. As micromechanical functional region 3, micromechanical component 1 includes an acceleration-sensitive module having a seismic mass, whose deflection is ascertained and evaluated by an evaluation circuit in the form of an ASIC as microelectronic component 16. Capacitors 17 integrated into micromechanical component 1 are utilized as buffer capacitors for ASIC 16, and are connected to it via corresponding lines 18. Alternatively, separate wiring of integrated capacitors 17 for other purposes is possible. Entire functional unit 20 is accommodated in a mold-housing 19, whereby a separate printed-circuit board for external interconnection may be saved or reduced in area.

One advantage of the present invention is that no complete IC process is required for the preparation for the integrated passive components, but simply the broadening of a method for producing the usual MEMS stacks is sufficient for producing components designed according to the present invention. In the present exemplary embodiment, this takes place by a method according to which a layer sequence is formed which is able to act as at least one buffer capacitor, in that, after the application of an insulating layer, preferably in the form of a thermal oxide layer, the following process steps are included in the method on a wafer of monocrystalline silicon:
depositing a first polycrystalline silicon layer on a silicon substrate;
doping the polycrystalline silicon layer, in order to make it conductive as the lower junction electrode;
cleaning the polycrystalline silicon layer using hydrofluoric acid, in order to remove an oxide layer close to the surface that appears after the doping;
photolithographic masking of the polycrystalline silicon layer;
etching patterning of the polycrystalline silicon layer, by which the geometry of the lower junction electrode is established;
removing the remaining photoresist from the future electrode surface;
depositing an oxide-nitride-oxide dielectric based on silicon, which is first begun by reactive depositing of a silicon dioxide layer, is continued by reactive depositing of a silicon nitride layer (Si₃N₄), and is then finished by a near-surface reoxidation of the silicon nitride layer;
photolithographic masking of the oxide-nitride-oxide dielectric,
etching patterning of the oxide-nitride-oxide dielectric, the patterning of the lower oxide layer in the layer stack of the dielectric taking place in a wet-chemical etching step;
removing the remaining photoresist from the dielectric;
installing a layer having buried printed-circuit traces.

The installation of the layer having buried printed-circuit traces represents a process step which contributes to the development of both functional regions of a micromechanical component according to the present invention. Depending on the contacting, conducting areas of this layer form an upper junction electrode of a capacitor structure lying below it, or lower contacting means of a micromechanical structure lying above it.

The broadening of the method according to the present invention brings about only slight additional costs for the integration of passive components, especially for the integration of large-area and simply patterned components, such as surface capacitors. These additional costs, for a backup capacitor of 1-2 nF, i less than one cent per chip.

What is claimed is:

1. A micromechanical component comprising:
a substrate;
at least one first layer sequence situated on the substrate, the at least one first layer sequence including at least one micromechanical functional element; and
at least one second layer sequence situated on the substrate, the at least one second layer sequence being able to act as at least one macroelectronic, passive component.

2. The micromechanical component according to claim 1, further comprising capacitors acting as passive electronic components.

3. The micromechanical component according to claim 1, wherein the second layer sequence is situated at least partially between the first layer sequence and the substrate.

4. The micromechanical component according to claim 1, wherein surface areas of the substrate above which layer stacks are situated, which are utilized as passive electronic components, and surface areas above which printed-circuit traces run for contacting micromechanically effective patternings, lie side by side in a wafer plane.

5. The micromechanical component according to claim 1, wherein surface areas of the substrate above which layer stacks are situated, which are utilized as passive electronic components, lie within an area of a bonding frame.

6. The micromechanical component according to claim 1, further comprising:
at least one insulating layer covering at least parts of the substrate;
at least one lower junction electrode situated on the insulating layer;
at least one lower dielectric layer situated on the lower junction electrode;
at least one upper junction electrode situated on the lower dielectric layer; and
at least one insulating layer situated on the upper junction electrode, as a component of the first layer sequence, which includes at least one micromechanical functional element.

7. The micromechanical component according to claim 6, wherein the upper junction electrode lies in a plane together with printed-circuit traces developed as buried printed-circuit traces, for contacting regions of the first layer sequence lying above them.

8. A system comprising:
at least one micromechanical component; and
at least one microelectronic component,
wherein the at least one micromechanical component is combined with the at least one microelectronic component, to form a functional unit, there being an interconnection inside the functional unit which incorporates capacitors, integrated into the micromechanical component, as buffer capacitors for the microelectronic component.

9. A method for producing a micromechanical component comprising:
producing at least one micromechanical functional layer on a substrate by successive depositing steps and patterning steps,
wherein at least one of (a) the depositing steps and (b) the patterning steps are undertaken which produce at least one layer sequence on the same substrate, which is able to act as at least one macroelectronic, passive component.

10. The method according to claim 9, wherein a layer sequence is produced which is able to act as at least one buffer capacitor for a microelectronic circuit, by performing the following:
depositing a polycrystalline silicon layer on a silicon substrate;
doping the polycrystalline silicon layer;
cleaning the polycrystalline silicon layer using hydrofluoric acid;
photolithographic masking of the polycrystalline silicon layer;
etching patterning of the polycrystalline silicon layer;
removing a remaining photoresist;
depositing an oxide-nitride-oxide dielectric based on silicon;
photolithographic masking of the oxide-nitride-oxide dielectric;
etching patterning of the oxide-nitride-oxide dielectric;
removing the remaining photoresist; and
installing a layer having buried printed-circuit traces.
